(19) United States
(12) Patent Application Publication
(10) Pub. No.: US 2026/0016332 A1
(43) Pub. Date: Jan. 15, 2026

(54) DETECTION DEVICE

(71) Applicants: Japan Display Inc., Tokyo (JP); The University of Tokyo, Tokyo (JP)

(72) Inventors: Keiichi SAITO, Tokyo (JP); Atsunori OYAMA, Tokyo (JP); Gen KOIDE, Tokyo (JP); Takashi NAKAMURA, Tokyo (JP); Takao SOMEYA, Tokyo (JP); Tomoyuki YOKOTA, Tokyo (JP); Ikue KAWASHIMA, Tokyo (JP)

(21) Appl. No.: 19/332,390

(22) Filed: Sep. 18, 2025

Related U.S. Application Data
(63) Continuation of application No. PCT/JP2024/009595, filed on Mar. 12, 2024.

(30) Foreign Application Priority Data
Mar. 23, 2023 (JP) 2023-046331

(51) Int. Cl. G01J 1/08; G01J 1/42

(52) U.S. Cl. CPC G01J 1/08; G01J 1/4228

(57) ABSTRACT

According to an aspect, a detection device includes: a first photodiode sensitive to at least a first wavelength range; a second photodiode sensitive to a second wavelength range and a third wavelength range that are different from the first wavelength range; a first light source configured to emit light in the first wavelength range and light in the second wavelength range; and a second light source configured to emit at least light in the third wavelength range. The first photodiode and the second photodiode are coupled in series with opposite polarity.

### CROSS-REFERENCE TO RELATED APPLICATION

This application claims the benefit of priority from Japanese Patent Application No. 2023-046331 filed on Mar. 23, 2023 and International Patent Application No. PCT/JP2024/009595 filed on Mar. 12, 2024, the entire contents of which are incorporated herein by reference.

### BACKGROUND

### 1. Technical Field

What is disclosed herein relates to a detection device.

### 2. Description of the Related Art

Organic photodiodes (OPDs) using organic semiconductor materials are known as optical sensors (for example, Japanese Patent Application Laid-open Publication No. 2019-160826).

When developing color scanners having sensitivity to different wavelengths using the OPDs, for example, a plurality types of photodiodes having detection sensitivities about red, green, and blue (RGB) colors need to be provided. This necessity makes it difficult to increase the arrangement density of pixels and may make it difficult to achieve a higher resolution in detection.

For the foregoing reasons, there is a need for a detection device that has good detection sensitivities about different wavelengths and is capable of achieving a higher resolution of detection using the OPDs.

### SUMMARY

According to an aspect, a detection device includes: a first photodiode sensitive to at least a first wavelength range; a second photodiode sensitive to a second wavelength range and a third wavelength range that are different from the first wavelength range; a first light source configured to emit light in the first wavelength range and light in the second wavelength range; and a second light source configured to emit at least light in the third wavelength range. The first photodiode and the second photodiode are coupled in series with opposite polarity.

### BRIEF DESCRIPTION OF THE DRAWINGS

FIG. 1 is a plan view schematically illustrating a detection device according to a first embodiment;

FIG. 2 is a block diagram illustrating a configuration example of the detection device according to the first embodiment;

FIG. 3 is a circuit diagram illustrating the detection device according to the first embodiment;

FIG. 4 is a circuit diagram illustrating sensor pixels and a detection circuit according to the first embodiment;

FIG. 5 is a sectional view schematically illustrating a section of first and second photodiodes;

FIG. 6 is a timing waveform diagram illustrating an operation example of the detection device according to the first embodiment;

FIG. 7 is a magnified timing waveform diagram illustrating an area P in FIG. 6;

FIG. 8 is a timing waveform diagram illustrating an operation example of a detection device according to a modification;

FIG. 9 is a circuit diagram illustrating the sensor pixels and the detection circuit of a detection device according to a second embodiment; and

FIG. 10 is a timing waveform diagram illustrating an operation example of the detection device according to the second embodiment.

### DETAILED DESCRIPTION

The following describes modes (embodiments) for carrying out the present disclosure in detail with reference to the drawings. The present disclosure is not limited to the description of the embodiments given below. Components described below include those easily conceivable by those skilled in the art or those substantially identical thereto. In addition, the components described below can be combined as appropriate. What is disclosed herein is merely an example, and the present disclosure naturally encompasses appropriate modifications easily conceivable by those skilled in the art while maintaining the gist of the present disclosure. To further clarify the description, the drawings may schematically illustrate, for example, widths, thicknesses, and shapes of various parts as compared with actual aspects thereof. However, they are merely examples, and interpretation of the present disclosure is not limited thereto. The same component as that described with reference to an already mentioned drawing is denoted by the same reference numeral through the present disclosure and the drawings, and detailed description thereof may not be repeated where appropriate.

In the present specification and claims, in expressing an aspect of disposing another structure on or above a certain structure, a case of simply expressing “on” includes both a case of disposing the other structure immediately on the certain structure so as to contact the certain structure and a case of disposing the other structure above the certain structure with still another structure interposed therebetween, unless otherwise specified.

### First Embodiment

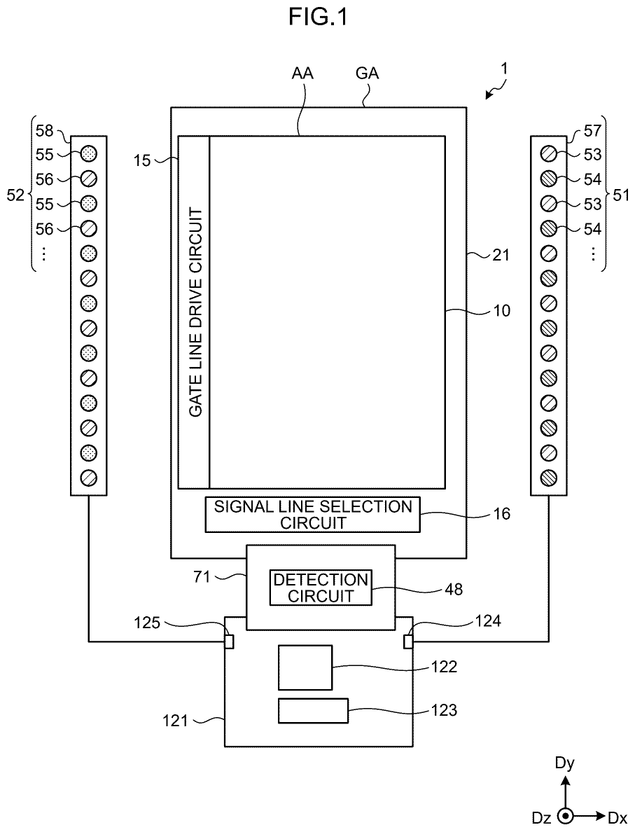

FIG. 1 is a plan view illustrating a detection device according to a first embodiment. A detection device 1 of the present embodiment includes an organic photodiode (OPD) as an optical sensor and is employed in color scanners and digital cameras that capture images of objects to be detected. As illustrated in FIG. 1, the detection device 1 includes a substrate 21, a sensor 10, a gate line drive circuit 15, a signal line selection circuit 16, a detection circuit 48, a control circuit 122, a power supply circuit 123, a first light source 51, and a second light source 52.

The substrate 21 is electrically coupled to a control substrate 121 through a wiring substrate 71. The wiring substrate 71 is, for example, a flexible printed circuit board or a rigid circuit board. The wiring substrate 71 is provided with the detection circuit 48. The control substrate 121 is provided with the control circuit 122 and the power supply circuit 123.

The control circuit 122 is a field-programmable gate array (FPGA), for example. The control circuit 122 supplies control signals to the sensor 10, the gate line drive circuit 15, and the signal line selection circuit 16 to control detection operations of the sensor 10. The control circuit 122 also supplies control signals to the first and the second light sources 51 and 52 to control lighting and non-lighting of light-emitting elements of the first and the second light sources 51 and 52.

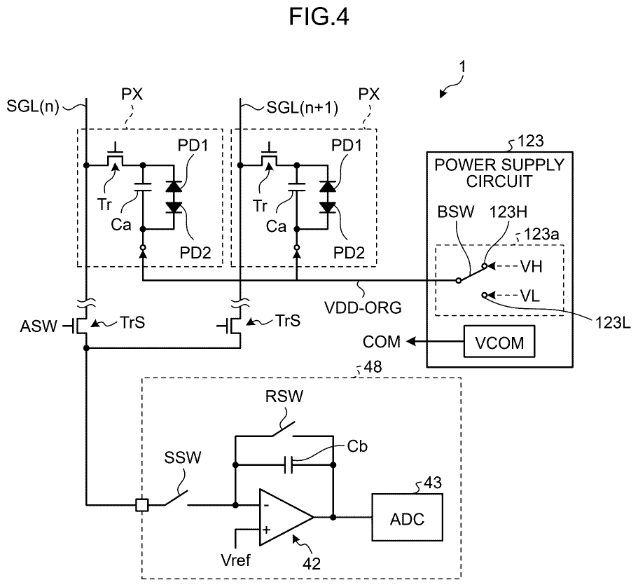

The power supply circuit 123 supplies voltage signals including, for example, a drive voltage VDD-ORG (refer to FIG. 4) to the sensor 10, the gate line drive circuit 15, and the signal line selection circuit 16. The power supply circuit 123 supplies a power supply voltage to the first and the second light sources 51 and 52.

The substrate 21 has a detection area AA and a peripheral area GA. The detection area AA is an area provided with a plurality of photodiodes PD (refer to FIG. 4) included in the sensor 10. The peripheral area GA is an area between the outer perimeter of the detection area AA and the outer edges of the substrate 21 and is an area not provided with the photodiodes PD.

The gate line drive circuit 15 and the signal line selection circuit 16 are provided in the peripheral area GA. Specifically, the gate line drive circuit 15 is provided in an area extending along a second direction Dy in the peripheral area GA. The signal line selection circuit 16 is provided in an area extending along a first direction Dx in the peripheral area GA and is provided between the sensor 10 and the detection circuit 48.

In the following description, the first direction Dx is a direction in a plane parallel to the substrate 21. The second direction Dy is a direction in the plane parallel to the substrate 21, and is a direction orthogonal to the first direction Dx. The second direction Dy may, however, non-orthogonally intersect the first direction Dx. A third direction Dz is a direction orthogonal to the first direction Dx and the second direction Dy. The third direction Dz is the normal direction of the substrate 21. The term “plan view” refers to a positional relation when viewed in a direction orthogonal to the substrate 21.

The first light source 51 includes a first light source base member 57, and a plurality of first light-emitting elements 53 and a plurality of second light-emitting elements 54 provided on the first light source base member 57. The first light source 51 is located outside one side of the sensor 10 (right side in FIG. 1) and arranged along the one side of the sensor 10. The first light-emitting elements 53 and the second light-emitting elements 54 are arranged alternately along the one side of the sensor 10.

The second light source 52 includes a second light source base member 58, and a plurality of third light-emitting elements 55 and a plurality of fourth light-emitting elements 56 provided on the second light source base member 58. The second light source 52 is located outside the other side of the sensor 10 (left side in FIG. 1) and arranged along the other side of the sensor 10. The third light-emitting elements 55 and the fourth light-emitting elements 56 are arranged alternately along the other side of the sensor 10.

The first and the second light sources 51 and 52 are electrically coupled to the control circuit 122 and the power supply circuit 123 through respective terminals 124 and 125 provided on the control substrate 121.

For example, inorganic light-emitting diodes (LEDs) or organic electroluminescent (EL) diodes (organic light-emitting diodes (OLEDs)) are used as the first, second, third, and fourth light-emitting elements 53, 54, 55, and 56. The first, second, third, and fourth light-emitting elements 53, 54, 55, and 56 emit light rays in different wavelength ranges from one another.

Specifically, the first light-emitting elements 53 emit light in a first wavelength range. The second light-emitting elements 54 emit light in a second wavelength range. The third light-emitting elements 55 emit light in a third wavelength range. The fourth light-emitting elements 56 emit light in a fourth wavelength range. The first wavelength range is a wavelength range of red light (hereinafter, denoted as R). The second wavelength range is a wavelength range of green light (hereinafter, denoted as G). The third wavelength range is a wavelength range of blue light (hereinafter, denoted as B). The fourth wavelength range is a wavelength range of near-infrared light (hereinafter, denoted as IR).

The first and the second light sources 51 and 52 are, however, not limited to this configuration, and may include a plurality of LEDs that emit white light. The light emitted from the first and the second light sources 51 and 52 is reflected on a surface of an object to be detected, and enters the sensor 10. Thus, the sensor 10 can image the object to be detected.

The arrangement of the light-emitting elements included in the first and the second light sources 51 and 52 can be changed as appropriate. For example, in the first light source 51, the first light-emitting elements 53 may be arranged in a line along the one side of the sensor 10, and the second light-emitting elements 54 may be arranged in a line along the arrangement direction of the first light-emitting elements 53 so as to be adjacent to the first light-emitting elements 53. In the second light source 52, the third light-emitting elements 55 may be arranged in a line along the other side of the sensor 10, and the fourth light-emitting elements 56 may be arranged in a line along the arrangement direction of the third light-emitting elements 55 so as to be adjacent to the third light-emitting elements 55.

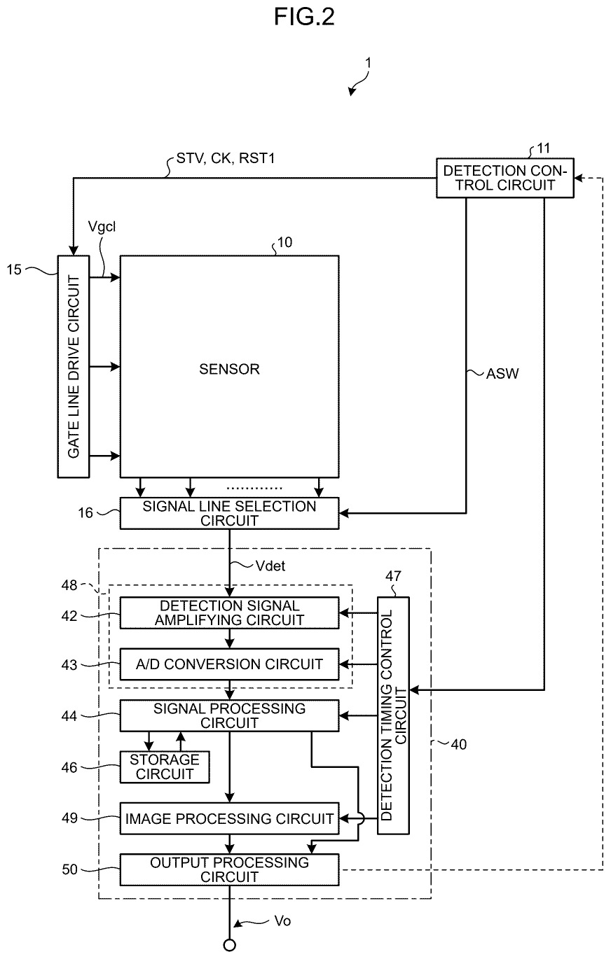

FIG. 2 is a block diagram illustrating a configuration example of the detection device according to the first embodiment. As illustrated in FIG. 2, the detection device 1 further includes a detection control circuit 11 and a detector (detection signal processing circuit) 40. The control circuit 122 includes one, some, or all functions of the detection control circuit 11. The control circuit 122 also includes one, some, or all functions of the detector 40 other than those of the detection circuit 48.

The sensor 10 includes the photodiodes PD. Each of the photodiodes PD included in the sensor 10 outputs an electrical signal corresponding to light irradiating the photodiode PD as an output signal Vdet to the signal line selection circuit 16. The sensor 10 performs detection in response to a gate drive signal Vgcl supplied from the gate line drive circuit 15.

The detection control circuit 11 is a circuit that supplies respective control signals to the gate line drive circuit 15, the signal line selection circuit 16, and the detector 40 to control operations of these components. The detection control circuit 11 supplies various control signals such as a start signal STV, a clock signal CK, and a reset signal RST1 to the gate line drive circuit 15. The detection control circuit 11 also supplies various control signals such as a selection signal ASW to the signal line selection circuit 16. The detection control circuit 11 also supplies various control signals to the first and the second light sources 51 and 52 to control the lighting and the non-lighting of each of the first and the second light sources 51 and 52.

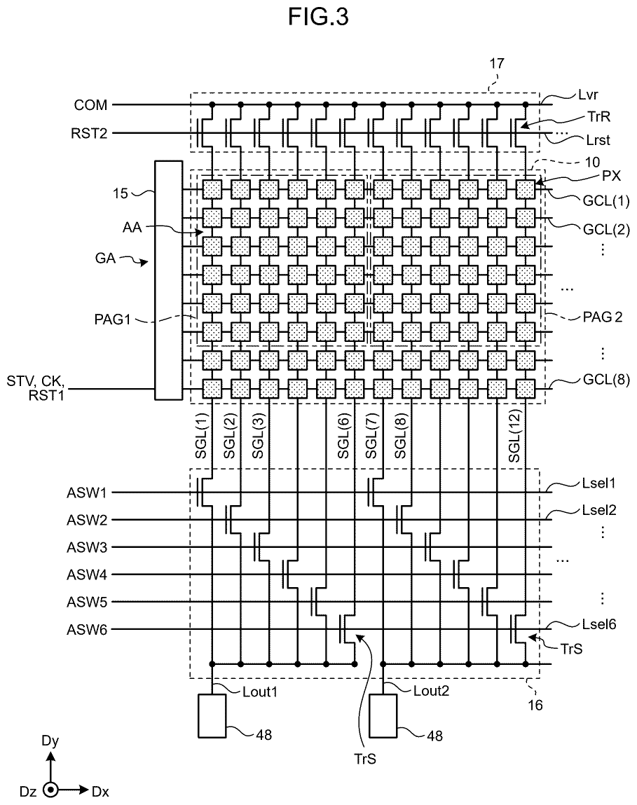

The gate line drive circuit 15 is a circuit that drives a plurality of gate lines GCL (refer to FIG. 3) based on the various control signals. The gate line drive circuit 15 sequentially or simultaneously selects the gate lines GCL and supplies the gate drive signals Vgcl to the selected gate lines GCL. By this operation, the gate line drive circuit 15 selects the photodiodes PD coupled to the gate lines GCL.

The signal line selection circuit 16 is a switch circuit that sequentially or simultaneously selects a plurality of signal lines SGL (refer to FIG. 3). The signal line selection circuit 16 is a multiplexer, for example. The signal line selection circuit 16 couples the selected signal lines SGL to the detection circuit 48 based on the selection signal ASW supplied from the detection control circuit 11. By this operation, the signal line selection circuit 16 outputs the output signal Vdet of the photodiode PD to the detector 40.

The detector 40 includes the detection circuit 48, a signal processing circuit 44, a storage circuit 46, a detection timing control circuit 47, an image processing circuit 49, and an output processing circuit 50. The detection timing control circuit 47 controls the detection circuit 48, the signal processing circuit 44, and the image processing circuit 49 to operate synchronously based on a control signal supplied from the detection control circuit 11.

The detection circuit 48 is an analog front-end (AFE) circuit, for example. The detection circuit 48 is a signal processing circuit having functions of at least a detection signal amplifying circuit 42 and an analog-to-digital (A/D) conversion circuit 43. The detection signal amplifying circuit 42 amplifies the output signal Vdet. The A/D conversion circuit 43 converts analog signals output from the detection signal amplifying circuit 42 into digital signals. The detection circuit 48 outputs red (R), green (G), and blue (B) color signals for each sensor pixel PX.

The signal processing circuit 44 performs predetermined adjustment on each of the red (R), green (G), and blue (B) color signals received from the detection circuit 48. For example, the signal processing circuit 44 performs the predetermined adjustment on the color signals so as to reduce variations in intensity of the light emitted from the first and the second light sources 51 and 52 within the detection area AA and variations in detection sensitivity of the photodiodes PD. The signal processing circuit 44 may also acquire the output signals Vdet simultaneously detected by the photodiodes PD and perform processing to average these signals. In this case, the detector 40 can reduce measurement errors that would otherwise be caused by noise or relative positional misalignment between the object to be detected and the sensor 10, thereby performing stable detection.

The storage circuit 46 temporarily stores therein signals calculated by the signal processing circuit 44. The storage circuit 46 may be, for example, a random-access memory (RAM) or a register circuit.

The image processing circuit 49 combines the output signals Vdet output from the photodiodes PD of the sensor 10 to generate two-dimensional information on an image. The image processing circuit 49 may output the output signals Vdet as sensor output voltages Vo instead of calculating the image data. A case may be considered where the detector 40 does not include the image processing circuit 49.

The output processing circuit 50 serves as a processor that performs processing based on the output from the photodiodes PD. The output processing circuit 50 may include the two-dimensional information and other information generated by the image processing circuit 49 in the sensor output voltages Vo. The functions of the output processing circuit 50 may be integrated into another component (such as the image processing circuit 49).

The following describes a circuit configuration example of the detection device 1. FIG. 3 is a circuit diagram illustrating the detection device according to the first embodiment. As illustrated in FIG. 3, the sensor 10 includes a plurality of the sensor pixels PX arranged in a matrix having a row-column configuration. Each of the sensor pixels PX is provided with the photodiode PD. The sensor pixels PX including the photodiodes PD are arranged on the substrate 21. The photodiode PD is an organic photodiode (OPD) using an organic semiconductor. A detailed configuration of the sensor pixels PX will be described later with reference to FIG. 4.

The gate lines GCL extend in the first direction Dx, and are each coupled to the sensor pixels PX arranged in the first direction Dx. A plurality of gate lines GCL(1), GCL(2), . . . , GCL(8) are arranged in the second direction Dy, and are each coupled to the gate line drive circuit 15. In the following description, the gate lines GCL(1), GCL(2), . . . , GCL(8) will each be simply referred to as the gate line GCL when need not be distinguished from one another. To facilitate understanding of the description, FIG. 3 illustrates eight gate lines GCL. However, this is merely an example, and M gate lines GCL may be arranged (where M is 8 or larger, such as 256).

The signal lines SGL extend in the second direction Dy and are each coupled to the photodiodes PD of the sensor pixels PX arranged in the second direction Dy. A plurality of signal lines SGL(1), SGL(2), . . . , SGL(12) are arranged in the first direction Dx, and are each coupled to the signal line selection circuit 16 and a reset circuit 17. In the following description, the signal lines SGL(1), SGL(2), . . . , SGL(12) will each be simply referred to as the signal line SGL when need not be distinguished from one another.

To facilitate understanding of the description, 12 signal lines SGL are illustrated. However, this is merely an example, and N signal lines SGL may be arranged (where N is a 12 or larger, such as 252). In FIG. 3, the sensor 10 is provided between the signal line selection circuit 16 and the reset circuit 17. The signal line selection circuit 16 and the reset circuit 17 are not limited to being provided in this way and may be coupled to ends of the signal lines SGL on the same side.

The gate line drive circuit 15 receives the various control signals such as the start signal STV, the clock signal CK, and the reset signal RST1 from the control circuit 122 (refer to FIG. 1). The gate line drive circuit 15 sequentially selects the gate lines GCL(1), GCL(2), . . . , GCL(8) in a time-division manner based on the various control signals. The gate line drive circuit 15 supplies the gate drive signal Vgcl to the selected one of the gate lines GCL. This operation supplies the gate drive signal Vgcl to a plurality of transistors Tr coupled to the gate line GCL, and thus selects the sensor pixels PX arranged in the first direction Dx as detection targets.

The signal line selection circuit 16 includes a plurality of selection signal lines Lsel, a plurality of output signal lines Lout, and output transistors TrS. The output transistors TrS are provided correspondingly to the signal lines SGL. Six signal lines SGL(1), SGL(2), . . . , SGL(6) are coupled to a common output signal line Lout1. Six signal lines SGL(7), SGL(8), . . . , SGL(12) are coupled to a common output signal line Lout2. The output signal lines Lout1 and Lout2 are each coupled to the detection circuit 48.

The signal lines SGL(1), SGL(2), . . . , SGL(6) are grouped into a first signal line block, and the signal lines SGL(7), SGL(8), . . . , SGL(12) are grouped into a second signal line block. The selection signal lines Lsel are coupled to the gates of the respective output transistors TrS included in one of the signal line blocks. One of the selection signal lines Lsel is coupled to the gates of the output transistors TrS in the signal line blocks.

The control circuit 122 (refer to FIG. 1) sequentially supplies the selection signals ASW to the selection signal lines Lsel. This operation causes the signal line selection circuit 16 to operate the output transistors Trs to sequentially select the signal lines SGL in one of the signal line blocks in a time-division manner. The signal line selection circuit 16 selects one of the signal lines SGL in each of the signal line blocks. Such a configuration can reduce the number of integrated circuits (ICs) including the detection circuit 48 or the number of terminals of the ICs in the detection device 1. The signal line selection circuit 16 may collectively couple more than one of the signal lines SGL to the detection circuit 48.

As illustrated in FIG. 3, the reset circuit 17 includes a reference signal line Lvr, a reset signal line Lrst, and reset transistors TrR. The reset transistors TrR are provided correspondingly to the signal lines SGL. The reference signal line Lvr is coupled to either the sources or the drains of the reset transistors TrR. The reset signal line Lrst is coupled to the gates of the reset transistors TrR.

The control circuit 122 supplies a reset signal RST2 to the reset signal line Lrst. This operation turns on the reset transistors TrR to electrically couple the signal lines SGL to the reference signal line Lvr. The power supply circuit 123 supplies a reference potential COM to the reference signal line Lvr. This operation supplies the reference potential COM to a capacitive element Ca included in each of the sensor pixels PX.

FIG. 4 is a circuit diagram illustrating the sensor pixels and the detection circuit according to the first embodiment. FIG. 4 also illustrates a circuit configuration of the power supply circuit 123. FIG. 4 illustrates two adjacent sensor pixels PX. The left sensor pixel PX is coupled to a signal line SGL(n). The right sensor pixel PX is coupled to a signal line SGL(n+1). The transistors Tr of two adjacent sensor pixels PX are coupled to the same gate line GCL(refer to FIG. 3). The sensor pixels PX have the same configuration as one another. In the following description, the signal lines SGL(n) and SGL(n+1) will each be simply referred to as the signal line SGL when need not be distinguished from each other.

As illustrated in FIG. 4, each of the sensor pixels PX includes a first photodiode PD1, a second photodiode PD2, the capacitive element Ca, and the transistor Tr. The first photodiode PD1 is sensitive to the first wavelength range (R) and the fourth wavelength range (IR) that is different from the first wavelength range (R). The second photodiode PD2 is sensitive to the second wavelength range (G) and the third wavelength range (B) that are different from the first wavelength range (R).

That is, the wavelength ranges (R, IR) to which the first photodiode PD1 is sensitive overlap a part of the wavelength range (R) of the light emitted from the first light source 51 (first light-emitting elements 53 (R) and second light-emitting elements 54 (G)). The wavelength ranges (R, IR) to which the first photodiode PD1 is sensitive overlap also a part of the wavelength range (IR) of the light emitted from the second light source 52 (third light-emitting elements 55 (B) and fourth light-emitting elements 56 (IR)).

The wavelength ranges (G, B) to which the second photodiode PD2 is sensitive overlap also a part of the wavelength range (G) of the light emitted from the first light source 51 (first light-emitting elements 53 (R) and second light-emitting elements 54 (G)). The wavelength ranges (G, B) to which the second photodiode PD2 is sensitive overlap also a part of the wavelength range (B) of the light emitted from the second light source 52 (third light-emitting elements 55 (B) and fourth light-emitting elements 56 (IR)).

In the following description, the first and the second photodiodes PD1 and PD2 will each be simply referred to as a “photodiode PD” when need not be distinguished from each other.

The first photodiode PD1 and the second photodiode PD2 are connected in series and with opposite polarity. The term “coupled with opposite polarity” indicates a coupling configuration in which the rectification characteristics of the first and the second photodiodes PD1 and PD2 are in the opposite directions.

More specifically, the anode of the first photodiode PD1 is electrically coupled to the anode of the second photodiode PD2. One end side of the first and the second photodiodes PD1 and PD2 coupled in series, that is, the cathode of the first photodiode PD1, is coupled to the signal line SGL via the transistor Tr. The other end side of the first and the second photodiodes PD1 and PD2 coupled in series, that is, the cathode of the second photodiode PD2, is electrically coupled to a drive signal supply circuit 123a (power supply circuit 123) and is supplied with the drive voltage VDD-ORG.

The capacitive element Ca is capacitance (sensor capacitance) generated in the photodiode PD and is equivalently coupled in parallel to the photodiodes PD (first and second photodiodes PD1 and PD2 coupled in series). In the sensor pixel PX, one end side of the capacitive element Ca is electrically coupled to the cathode of the first photodiode PD1, and the other end side of the capacitive element Ca is electrically coupled to the cathode of the second photodiode PD2.

The transistor Tr is provided correspondingly to the photodiodes PD (first and second photodiodes PD1 and PD2). The transistor Tr is configured as a thin-film transistor, and in this example, configured as an n-channel metal oxide semiconductor (MOS) thin-film transistor (TFT).

The gate of the transistor Tr is coupled to the gate line GCL (refer to FIG. 3). The source of the transistor Tr is coupled to the signal line SGL. The drain of the transistor Tr is coupled to the cathode of the first photodiode PD1 and the one and side of the capacitive element Ca.

The reference potential COM serving as an initial potential of the signal lines SGL and the photodiodes PD is supplied from the power supply circuit 123 to the signal lines SGL(signal lines SGL(n) and SGL(n+1)) and the cathodes of the first photodiodes PD1. Each of the photodiodes PD is supplied with a bias voltage VB by the drive voltage VDD-ORG and the reference potential COM. The bias voltage VB is expressed as VB=COM−(VDD−ORG). In more detail, as described above, the drive voltage VDD-ORG is supplied to the other end side of the first and the second photodiodes PD1 and PD2 coupled in series, that is, the cathode of the second photodiode PD2, and the reference potential COM is supplied to the one end side of the first and the second photodiodes PD1 and PD2 coupled in series, that is, the cathode of the first photodiode PD1. Since one and the other of the first and the second photodiodes PD1 and PD2 coupled in series are forward biased and reverse biased, respectively, different voltages are applied to the first and the second photodiodes PD1 and PD2.

As described above, the drive signal supply circuit 123a supplies the drive voltage VDD-ORG to each of the photodiodes PD of the sensor pixels PX. In more detail, the drive signal supply circuit 123a supplies the drive voltage VDD-ORG to the other end side of the first and the second photodiodes PD1 and PD2 coupled in series, that is, the cathode of the second photodiode PD2. The drive signal supply circuit 123a includes a first voltage signal supply circuit 123H, a second voltage signal supply circuit 123L, and a switch BSW. The first voltage signal supply circuit 123H is a circuit that supplies a first voltage signal VH having a higher level voltage than the reference potential COM. The second voltage signal supply circuit 123L is a circuit that supplies a second voltage signal VL having a lower level voltage than the reference potential COM. The switch BSW is a switch element that switches the state of coupling of the first voltage signal supply circuit 123H and the second voltage signal supply circuit 123L to each of the photodiodes PD of the sensor pixels PX.

By operating the switch BSW, the drive signal supply circuit 123a supplies the first voltage signal VH and the second voltage signal VL to each of the photodiodes PD of the sensor pixels PX in a time-division manner. In other words, the polarity of the drive voltage VDD-ORG supplied to the first and the second photodiodes PD1 and PD2 coupled in series is switched alternately for each period. In each period, one of the first and the second photodiodes PD1 and PD2 is driven in a reverse-biased manner and becomes active. In the present disclosure, the term “active state” refers to a state in which the photodiode PD is supplied with a reverse bias voltage and can detect light emitted thereto.

Specifically, when the first voltage signal VH (VH>COM) is supplied from the drive signal supply circuit 123a to the cathode of the second photodiode PD2, the first photodiode PD1 is driven in a forward-biased manner and the second photodiode PD2 is driven in a reverse-biased manner. In this case, the second photodiode PD2 detects light in the second wavelength range (G) and light in the third wavelength range (B), and a current in a forward direction flows in the first photodiode PD1. In other words, the first photodiode PD1 is refreshed in synchronization with the detection period during which the second photodiode PD2 performs detection. In the present disclosure, the term “refresh operation” refers to an operation to return the characteristics of the OPD to an initial state by applying a forward-biased current to the photodiode PD.

When the second voltage signal VL (VL<COM) is supplied from the drive signal supply circuit 123a to the cathode of the second photodiode PD2, the first photodiode PD1 is driven in a reverse-biased manner and the second photodiode PD2 is driven in a forward-biased manner. In this case, the first photodiode PD1 detects light in the first wavelength range (R) and the fourth wavelength range (IR), and a current in a forward direction flows in the second photodiode PD2, which is thereby refreshed.

Thus, the detection device 1 performs the detection of the red light (R) and the near-infrared light (IR) by the first photodiode PD1 and the detection of the green light (G) and the blue light (B) by the second photodiode PD2 in a time-division manner in one sensor pixel PX.

When the sensor pixel PX is irradiated with light, a current corresponding to the amount of the light flows through the photodiode PD (photodiode PD driven in a reverse-biased manner of the first and the second photodiodes PD1 and PD2). As a result, an electric charge is stored in the capacitive element Ca. When the transistor Tr is turned on, a current corresponding to the electric charge stored in the capacitive element Ca flows through the signal line SGL. The signal line SGL is electrically coupled to the detection circuit 48 via the output transistor TrS of the signal line selection circuit 16. Thus, the detection device 1 can detect a signal corresponding to the amount of the light irradiating the photodiode PD for each of the sensor pixels PX.

During a readout period, a switch SSW is turned on to couple the detection circuit 48 to the signal line SGL. The detection signal amplifying circuit 42 of the detection circuit 48 converts a current or an electric charge supplied from the signal line SGL into a voltage corresponding thereto. A reference potential (Vref) having a fixed potential is supplied to the non-inverting input portion (+) of the detection signal amplifying circuit 42, and the signal line SGL is coupled to the inverting input portion (−) of the detection signal amplifying circuit 42. In the present embodiment, the same signal as the reference potential COM is supplied as the reference potential (Vref).

The signal processing circuit 44 (refer to FIG. 2) calculates the difference between the output signal Vdet obtained when the photodiode PD is irradiated with light and the output signal Vdet obtained when the photodiode PD is not irradiated with light, as each of the sensor output voltages Vo. The detection signal amplifying circuit 42 includes a capacitive element Cb and a reset switch RSW. During a reset period, the reset switch RSW is turned on to reset the electric charge of the capacitive element Cb.

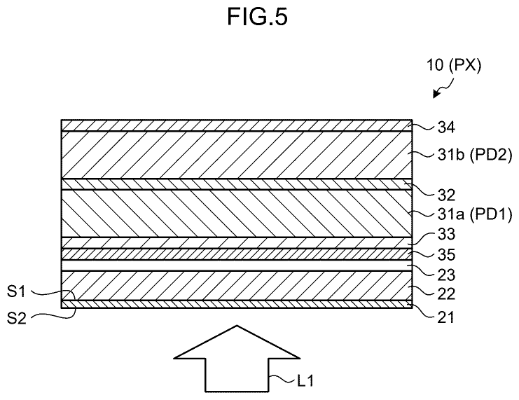

The following describes a configuration of the photodiode PD. FIG. 5 is a sectional view schematically illustrating a section of the first and the second photodiodes. As illustrated in FIG. 5, in the first and the second photodiodes PD1 and PD2 of the sensor 10, a lower electrode 35, a lower buffer layer 33, a first active layer 31a, an upper buffer layer 32, a second active layer 31b, and an upper electrode 34 are stacked above the substrate 21.

In more detail, the sensor 10 include a circuit forming layer 22 and an insulating layer 23 between the substrate 21 and the lower electrode 35 of the photodiode PD. The sensor 10 may also include a sealing layer and a protective layer on the upper electrode 34 as required.

The substrate 21 is an insulating base member and is made using, for example, glass or a resin material. The substrate 21 is not limited to having a flat plate shape, but may have a curved surface. In this case, the substrate 21 may be made of a film-like resin. The substrate 21 has a first surface S1 and a second surface S2 opposite to the first surface S1. The circuit forming layer 22, the insulating layer 23, the lower electrode 35, the lower buffer layer 33, the first active layer 31a, the upper buffer layer 32, the second active layer 31b, and the upper electrode 34 are stacked in this order on the first surface S1. In the present embodiment, a configuration will be described in which light L1 irradiates the photodiode PD from the second surface S2 side thereof. However, the configuration is not limited thereto. The light L1 may irradiate the photodiode PD from the first surface S1 side thereof.

The circuit forming layer 22 is provided with circuits such as the gate line drive circuit 15 and the signal line selection circuit 16 described above. The circuit forming layer 22 is also provided with TFTs, such as the transistors Tr included in the sensor pixels PX, and various types of wiring such as the gate lines GCL and the signal lines SGL. The substrate 21 and the circuit forming layer 22 are a drive circuit board that drives the sensor for each predetermined detection area, and are also called a backplane or an array substrate.

The insulating layer 23 is an organic insulating layer and is provided on the circuit forming layer 22. The insulating layer 23 is a planarizing layer that planarizes asperities formed by the transistors Tr and various conductive layers formed in the circuit forming layer 22.

The lower electrode 35 is provided on the insulating layer 23 and is electrically coupled to the transistor Tr in the circuit forming layer 22 through a contact hole (not illustrated). The lower electrode 35 is the cathode of the first photodiode PD1 and is an electrode for reading out the output signal Vdet. The lower electrode 35 is formed, for example, of a light-transmitting conductive material such as indium tin oxide (ITO).

The first and the second active layers 31a and 31b change in characteristics (for example, voltage-current characteristics and resistance values) depending on light emitted thereto. Organic materials are used as materials of the first and the second active layers 31a and 31b. Specifically, the first and the second active layers 31a and 31b have each a bulk heterostructure containing a mixture of a p-type organic semiconductor and an n-type organic semiconductor.

The first active layer 31a (first photodiode PD1) is sensitive to the first wavelength range (R) and the fourth wavelength range (IR). For example, the first active layer 31a is formed of a mixture of PCDTBT:PC70BM and DPP-DTT:PC70BM. PCDTBT:PC70BM is made by blending poly(N-9′-heptadecanyl-2,7-carbazole-alt-5,5) with (4′,7′-di-2-phenyl-2′,1′,3′ methyl butyrate). DPP-DTT:PC70BM is made by blending diketopyrrolopyrrole-dichlorodiphenyltrichloroethane with (4′,7′-di-2-phenyl-2′,1′,3′ methyl butyrate).

The second active layer 31b is sensitive to the second wavelength range (G) and the third wavelength range (B). For example, the second active layer 31b is formed of 1a:fullerene (C₆₀) that is a low-molecular-weight organic material.

The materials of the first and the second active layers 31a and 31b are only examples, and other materials may be used, or other materials may be combined with the materials mentioned above depending on the wavelength ranges of the detection targets.

The upper electrode 34 is the cathode of the second photodiode PD2 and is an electrode used to supply the drive voltage VDD-ORG to the photodiode PD. The upper electrode 34 and the lower electrode 35 face each other with the first and the second active layers 31a and 31b interposed therebetween. For example, aluminum (Al) is used as the upper electrode 34. Alternatively, the upper electrode 34 may be a metal material such as silver (Ag), or an alloy material containing at least one or more of these metal materials.

The lower buffer layer 33 and the upper buffer layer 32 are provided to facilitate holes and electrons generated in the first and the second active layers 31a and 31b to reach the upper electrode 34 or the lower electrode 35. The lower buffer layer 33 is an electron transport layer and is provided between the lower electrode 35 and the first active layer 31a in a direction orthogonal to the first surface S1 of the substrate 21. Polyethylenimine ethoxylated (PEIE), for example, is used as a material of the lower buffer layer 33.

The upper buffer layer 32 is a hole transport layer and is provided between the first active layer 31a and the second active layer 31b in the direction orthogonal to the first surface S1 of the substrate 21. As the upper buffer layer 32, a polythiophene-based conductive polymer poly(3,4-ethylenedioxythiophene) (PEDOT):poly(styrene sulfonate) (PSS) is used. In the present embodiment, the upper buffer layer 32 is shared by the first and the second photodiodes PD1 and PD2.

In the present embodiment, the configuration in which the light L1 irradiates the photodiode PD from the second surface S2 side has been described, but the light L1 may irradiate the photodiode PD from the first surface S1 side. In this case, a light-transmitting conductive material such as ITO is used as the upper electrode 34, and a metal material such as aluminum or silver is used as the lower electrode 35. The upper electrode 34 may be made light-transmitting by thinning the metal material.

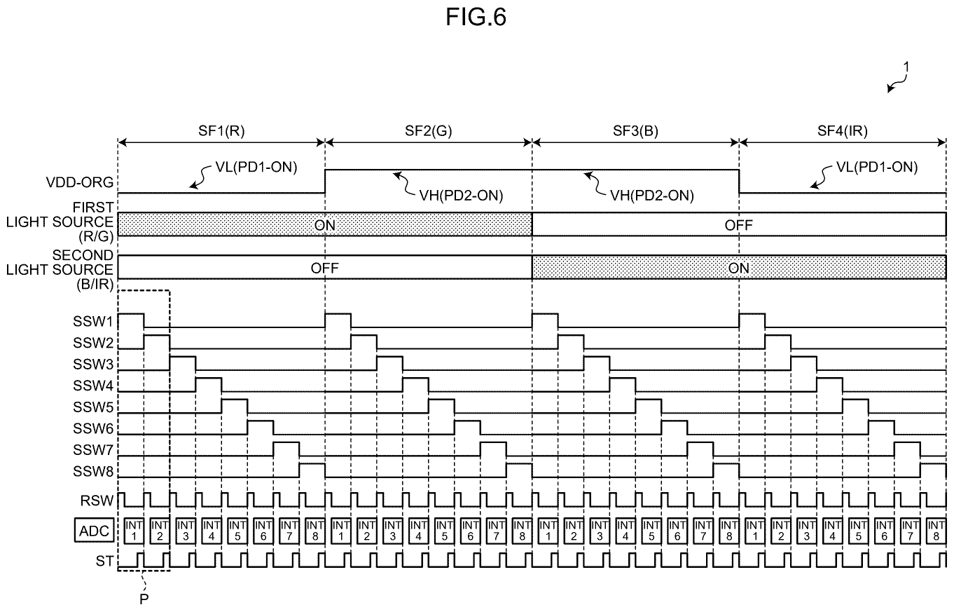

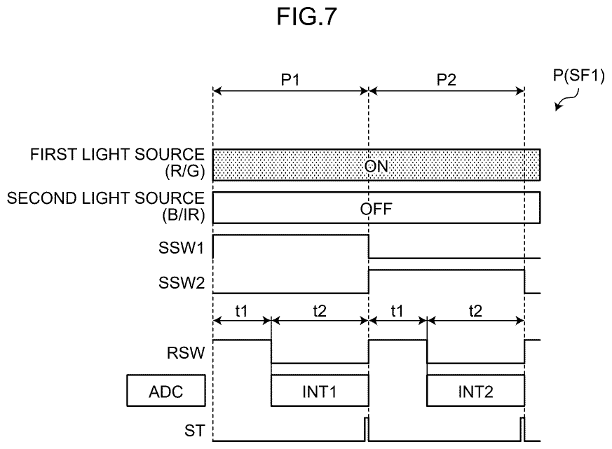

The following describes an operation example of the detection device 1. FIG. 6 is a timing waveform diagram illustrating the operation example of the detection device according to the first embodiment. FIG. 7 is a magnified timing waveform diagram illustrating a region P in FIG. 6. The detection device 1 divides one frame period for scanning the photodiodes PD in the detection area AA into a plurality of sub-frame periods SF and detects light in different wavelength range for each of the sub-frame periods SF.

The detection device 1 has a first period SF1, a second period SF2, a third period SF3, and a fourth period SF4 as the sub-frame periods SF. The detection device 1 detects light in the first wavelength range (R) in the first period SF1. The detection device 1 detects light in the second wavelength range (G) in the second period SF2. The detection device 1 detects light in the third wavelength range (B) in the third period SF3. The detection device 1 detects light in the fourth wavelength range (IR) in the fourth period SF4.

The detection device 1 controls the driving (active state and inactive state) of the first and the second photodiodes PD1 and PD2 for each of the sub-frame periods SF. The detection device 1 also controls the driving (on and off) of the first and the second light sources 51 and 52 for each of the sub-frame periods SF.

In more detail, in the first period SF1, the drive signal supply circuit 123a supplies the second voltage signal VL as the drive voltage VDD-ORG. As a result, the first photodiode PD1 is driven in a reverse-biased manner, and the second photodiode PD2 is driven in a forward-biased manner.

In the first period SF1, the first light source 51 is controlled to be on (ON) and the second light source 52 is controlled to be off (OFF) based on a control signal from the control circuit 122. The first light-emitting elements 53 of the first light source 51 emit light in the first wavelength range (R), and the second light-emitting elements 54 thereof emit light in the second wavelength range (G).

The first photodiode PD1 that becomes active in the first period SF1 is sensitive to light in the first wavelength range (R) and not sensitive (less sensitive) to light in the second wavelength range (G) among the wavelength ranges of the light emitted from the first light source 51. As a result, the detection device 1 detects light in the first wavelength range (R) in the first period SF1. In other words, in the first period SF1, the first and the second light-emitting elements 53 and 54 of the first light source 51 are controlled to be on simultaneously, without the need to individually control the on and off of the first and the second light-emitting elements 53 and 54.

FIG. 6 illustrates an example in which the detection circuit 48 is coupled to each of the signal line blocks. In this case, one of the selection signals ASW is assumed to be on in each of the signal line blocks. In the first period SF1, switches SSW1, SSW2, . . . , SSW8 of each of the detection circuits 48 are sequentially turned on in a time-division manner. This operation couples the detection circuits 48 corresponding to the switches SSW1, SSW2, SSW8 to the signal lines SGL.

As illustrated in FIG. 7, the switch SSW1 is on during a partial period P1, and the switch Ssw2 is on during a partial period P2. The partial periods P1 and P2 each have a reset period t1 and a readout period t2. In the reset period t1, the reset switch RSW included in the detection circuit 48 is turned on to reset the electric charge of the capacitive element Cb. During the readout period t2, the detection signal amplifying circuit 42 and the A/D conversion circuit 43 of the detection circuit 48 perform signal processing to output the sensor output voltage Vo. The on and off of the switches SSW1 and SSW2 in the partial periods P1 and P2 are controlled based on a control signal ST from the control circuit 122.

During a period when both the switch SSW and the reset switch RSW are on, a voltage equivalent to the reference potential Vref is applied to the signal line SGL where the selection signal ASW is on due to a virtual short circuit of the amplifier, so that a photocurrent generated only during the readout period t2 is stored as an electric charge in the capacitive element Cb.

Then, in the second period SF2, the drive signal supply circuit 123a supplies the first voltage signal VH as the drive voltage VDD-ORG. As a result, the first photodiode PD1 is driven in a forward-biased manner, and the second photodiode PD2 is driven in a reverse-biased manner.

In the second period SF2, the first light source 51 is controlled to be on (ON) and the second light source 52 is controlled to be off (OFF) based on the control signal from the control circuit 122. The driving of the first and the second light sources 51 and 52 remains in the same state over the first and the second periods SF1 and SF2. That is, the first light-emitting elements 53 of the first light source 51 emit light in the first wavelength range (R), and the second light-emitting elements 54 thereof emit light in the second wavelength range (G).

The second photodiode PD2 that becomes active in the second period SF2 is sensitive to light in the second wavelength range (G) and not sensitive (less sensitive) to light in the first wavelength range (R) among the wavelength ranges of the light emitted from the first light source 51. As a result, the detection device 1 detects light in the second wavelength range (G) in the second period SF2. In other words, in the second period SF2, the first and the second light-emitting elements 53 and 54 of the first light source 51 are controlled to be on simultaneously, continuously from the first period SF1, without the need to individually control the on and off of the first and the second light-emitting elements 53 and 54.

Then, in the third period SF3, the drive signal supply circuit 123a supplies the first voltage signal VH as the drive voltage VDD-ORG. The driving of the first and the second photodiodes PD1 and PD2 remains the same over the second and the third periods SF2 and SF3. That is, the first photodiode PD1 is driven in a forward-biased manner, and the second photodiode PD2 is driven in a reverse-biased manner.

In the third period SF3, the first light source 51 is controlled to be off (OFF) and the second light source 52 is controlled to be on (ON) based on the control signal from the control circuit 122. The third light-emitting elements 55 of the second light source 52 emit light in the third wavelength range (B), and the fourth light-emitting elements 56 of the second light source 52 emit light in the fourth wavelength range (IR).

The second photodiode PD2 that becomes active in the third period SF3 is sensitive to light in the third wavelength range (B) and not sensitive (less sensitive) to light in the fourth wavelength range (IR) among the wavelength ranges of the light emitted from the second light source 52. As a result, the detection device 1 detects light in the third wavelength range (B) in the third period SF3. In other words, in the third period SF3, the third and the fourth light-emitting elements 55 and 56 of the second light source 52 are controlled to be on simultaneously, without the need to individually control the on and off of the third and the fourth light-emitting elements 55 and 56.

Then, in the fourth period SF4, the drive signal supply circuit 123a supplies the second voltage signal VL as the drive voltage VDD-ORG. As a result, the first photodiode PD1 is driven in a reverse-biased manner, and the second photodiode PD2 is driven in a forward-biased manner.

In the fourth period SF4, the first light source 51 is controlled to be off (OFF) and the second light source 52 is controlled to be on (ON) based on the control signal from the control circuit 122. The driving of the first and the second light sources 51 and 52 remains in the same state over the third and the fourth periods SF3 and SF4. That is, the third light-emitting elements 55 of the second light source 52 emit light in the third wavelength range (B), and the fourth light-emitting elements 56 of the second light source 52 emit light in the fourth wavelength range (IR).

The first photodiode PD1 that becomes active in the fourth period SF4 is sensitive to light in the fourth wavelength range (IR) and not sensitive (less sensitive) to light in the third wavelength range (B) among the wavelength ranges of the light emitted from the second light source 52. As a result, the detection device 1 detects light in the fourth wavelength range (IR) in the fourth period SF4. In other words, in the fourth period SF4, the third and the fourth light-emitting elements 55 and 56 of the second light source 52 are controlled to be on simultaneously, continuously from the third period SF3, without the need to individually control the on and off of the third and the fourth light-emitting elements 55 and 56.

As described above, the detection device 1 can detect the light rays in different wavelength ranges at one sensor pixel PX by combining the driving of the first and the second photodiodes PD1 and PD2 with the driving of the first and the second light sources 51 and 52 in each period.

More specifically, the light rays in four different wavelength ranges can be detected by providing two types of photodiodes PD (the first photodiode PD1 sensitive to the first and fourth wavelength ranges, and the second photodiode PD2 sensitive to the second and the third wavelength ranges). Therefore, compared with a case where four types of photodiodes PD are provided correspondingly to the four different wavelength ranges, the arrangement pitch of the sensor pixels PX can be reduced, and the detection with higher definition can be achieved.

Since the first and the second photodiodes PD1 and PD2 are coupled in series with opposite polarity, the active states of the first and the second photodiodes PD1 and PD2 can be controlled only by switching the polarity of the drive voltage VDD-ORG. That is, the first and the second photodiodes PD1 and PD2 can be controlled more easily than when controlling the active state of each of the four types of photodiodes PD correspondingly to the four different wavelength ranges.

In each of the first period SF1 to the fourth period SF4, the two types of light sources: the first and second light sources 51 and 52 are controlled to be on and off, thereby enabling the detection of the light rays in the four different wavelength ranges. More specifically, in the first light source 51, the first light-emitting elements 53 and the second light-emitting elements 54 are synchronously controlled to be on and off. In the second light source 52, the third light-emitting elements 55 and the fourth light-emitting elements 56 are synchronously controlled to be on and off. That is, the first and the second light sources 51 and 52 can be controlled more easily than when individually controlling the first, the second, the third, and the fourth light-emitting elements 53, 54, 55, and 56.

The configuration of the first and the second photodiodes PD1 and PD2 illustrated in FIG. 5 and other figures explained above and the operation example illustrated in FIGS. 6 and 7 are merely exemplary, and can be changed as appropriate. For example, the first photodiode PD1 is sensitive to the first wavelength range (R) and the fourth wavelength range (IR), but the present disclosure is not limited thereto. The first photodiode PD1 only needs to be sensitive to at least the first wavelength range (R).

Specifically, the first active layer 31a of the first photodiode PD1 only needs to be sensitive to the first wavelength range (R). The first active layer 31a may be formed of PCDTBT:PC70BM and need not include DPP-DTT:PC70BM. The second active layer 31b of the second photodiode PD2 is sensitive to the second wavelength range (G) and the third wavelength range (B), in the same way as in the example described above. The second active layer 31b is formed of 1a:fullerene (C₆₀).

In this case, the second light source 52 may include the third light-emitting elements 55 that emit at least light in the third wavelength range (B) and need not include the fourth light-emitting elements 56 that emit light in the fourth wavelength range (IR). In the timing waveform diagram illustrated in FIG. 6, the detection device 1 can omit the fourth period SF4. That is, during the first period SF1 when the first photodiode PD1 is driven in a reverse-biased manner, the first light source 51 is on and the second light source 52 is off. During the second and the third periods SF2 and SF3 when the second photodiode PD2 is driven in a reverse-biased manner, one of the first and the second light sources 51 and 52 is on and the other of the first and the second light sources 51 and 52 is off. In such a configuration, the detection device 1 can detect light in the first wavelength range (R), light in the second wavelength range (G), and light in the third wavelength range (B) in the first period SF1, the second period SF2, and the third period SF3, respectively.

### Modification

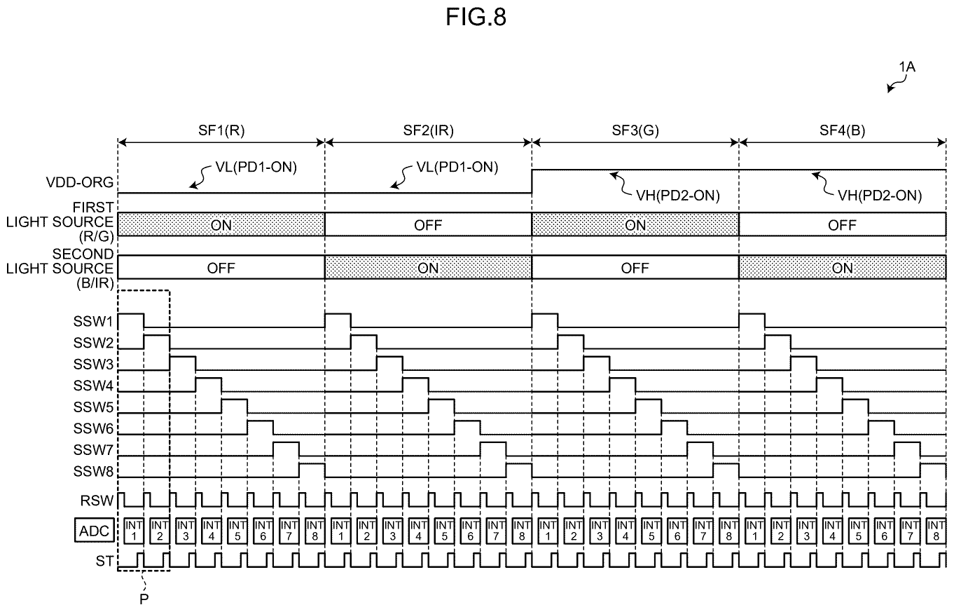

FIG. 8 is a timing waveform diagram illustrating an operation example of a detection device according to a modification. In the following description, the same components as those described in the embodiment described above are denoted by the same reference numerals, and the description thereof will not be repeated.

As illustrated in FIG. 8, in a detection device 1A according to the modification, during the first period SF1, the first photodiode PD1 is driven in a reverse-biased manner; and the first light source 51 is controlled to be on, and the second light source 52 is controlled to be off. The detection device 1A detects light in the first wavelength range (R) in the first period SF1. The operation in the first period SF1 in the modification is the same as that in the first period SF1 in the first embodiment described above and will not be described again.

During the second period SF2, the first photodiode PD1 is driven in a reverse-biased manner; and the second light source 52 is controlled to be on, and the first light source 51 is controlled to be off. The detection device 1A detects light in the fourth wavelength range (IR) in the second period SF2. The operation in the second period SF2 in the modification is the same as that in the fourth period SF4 in the first embodiment described above and will not be described again.

During the third period SF3, the second photodiode PD2 is driven in a reverse-biased manner; and the first light source 51 is controlled to be on, and the second light source 52 is controlled to be off. The detection device 1A detects light in the second wavelength range (G) in the third period SF3. The operation in the third period SF3 in the modification is the same as that in the second period SF2 in the first embodiment described above and will not be described again.

During the fourth period SF4, the second photodiode PD2 in a reverse-biased manner; and the second light source 52 is controlled to be on, and the first light source 51 is controlled to be off. The detection device 1A detects light in the third wavelength range (B) in the fourth period SF4. The operation in the fourth period SF4 in the modification is the same as that in the third period SF3 in the first embodiment described above and will not be described again.

The order of detection of light in the first wavelength range (R), light in the second wavelength range (G), light in the third wavelength range (B), and light in the fourth wavelength range (IR) is not limited to the examples illustrated in FIGS. 6 and 8, and may be any order.

### Second Embodiment

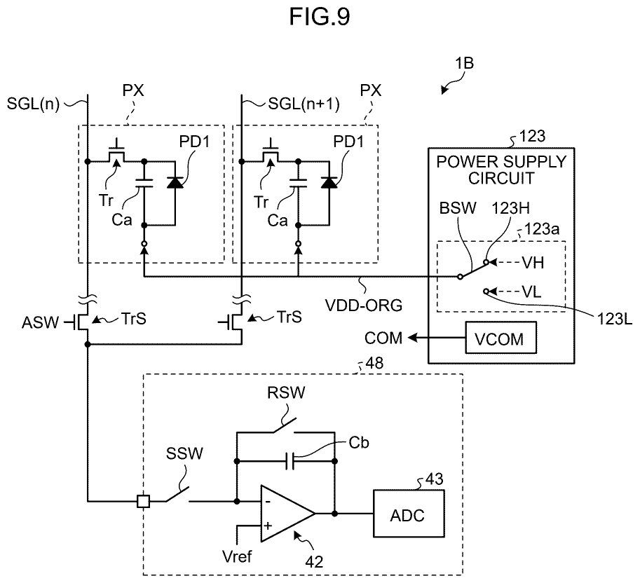

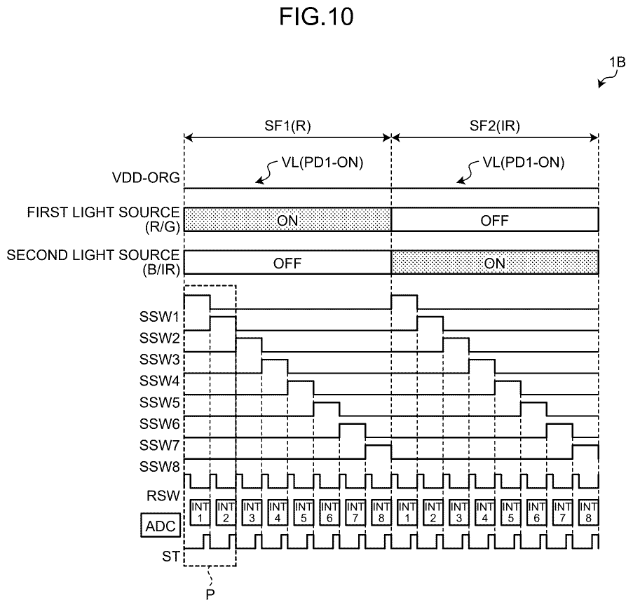

FIG. 9 is a circuit diagram illustrating the sensor pixels and the detection circuit of a detection device according to a second embodiment. FIG. 10 is a timing waveform diagram illustrating an operation example of the detection device according to the second embodiment.

As illustrated in FIG. 9, in a detection device 1B according to the second embodiment, the sensor pixel PX includes the first photodiode PD1 and does not include the second photodiode PD2. That is, the cathode of the first photodiode PD1 is coupled to the signal line SGL via the transistor Tr. The anode of the first photodiode PD1 is electrically coupled to the drive signal supply circuit 123a (power supply circuit 123) and is supplied with the drive voltage VDD-ORG.

When the first voltage signal VH (VH>COM) is supplied from the drive signal supply circuit 123a to the anode of the first photodiode PD1, the first photodiode PD1 is driven in a forward-biased manner, and the first photodiode PD1 is refreshed. When the second voltage signal VL (VL<COM) is supplied from the drive signal supply circuit 123a to the anode of the first photodiode PD1, the first photodiode PD1 is driven in a reverse-biased manner and becomes active. In this case, the first photodiode PD1 detects light in the first wavelength range (R) and light in the fourth wavelength range (IR).

As illustrated in FIG. 10, in the detection device 1B according to the second embodiment, during the first period SF1, the first photodiode PD1 is driven in a reverse-biased manner; and the first light source 51 is controlled to be on, and the second light source 52 is controlled to be off. The detection device 1B detects light in the first wavelength range (R) in the first period SF1.

During the second period SF2, the first photodiode PD1 is driven in a reverse-biased manner; and the second light source 52 is controlled to be on, and the first light source 51 is controlled to be off. The detection device 1B detects light in the fourth wavelength range (IR) in the second period SF2.

Thus, in the detection device 1B according to the second embodiment, light rays in two different wavelength ranges (R and IR) can be detected using a single type of first photodiodes PD1 and two types of light sources (first light source 51 and second light source 52).

In the second embodiment, a configuration with the second photodiode PD2 instead of the first photodiode PD1 can be employed. In this case, when the first voltage signal VH (VH>COM) is supplied from the drive signal supply circuit 123a to the cathode of the second photodiode PD2, the second photodiode PD2 is driven in a reverse-biased manner and becomes active. Light rays in two different wavelength ranges (blue and green) can be detected using a single type of second photodiodes PD2 and two types of light sources (first light source 51 and second light source 52).

While the preferred embodiments of the present disclosure have been described above, the present disclosure is not limited to the embodiments described above. The content disclosed in the embodiments is merely an example, and can be variously modified within the scope not departing from the gist of the present disclosure. Any modifications appropriately made within the scope not departing from the gist of the present disclosure also naturally belong to the technical scope of the present disclosure. At least one of various omissions, substitutions, and changes of the components can be made without departing from the gist of the embodiments described above and the modifications thereof.

What is claimed is:

1. A detection device comprising:
a first photodiode sensitive to at least a first wavelength range;
a second photodiode sensitive to a second wavelength range and a third wavelength range that are different from the first wavelength range;
a first light source configured to emit light in the first wavelength range and light in the second wavelength range; and
a second light source configured to emit at least light in the third wavelength range, wherein
the first photodiode and the second photodiode are coupled in series with opposite polarity.

2. The detection device according to claim 1, wherein
the first photodiode is sensitive to the first wavelength range and a fourth wavelength range different from the first wavelength range, and
the second light source is configured to emit light in the third wavelength range and light in the fourth wavelength range.

3. The detection device according to claim 1, wherein
the first light source is controlled to be on and the second light source is controlled to be off during a period when the first photodiode is driven in a reverse-biased manner, and
one of the first light source and the second light source is controlled to be on and another of the first light source and the second light source is controlled to be off during a period when the second photodiode is driven in a reverse-biased manner.

4. The detection device according to claim 1, wherein
a polarity of a drive voltage supplied to the first photodiode and the second photodiode coupled in series is switched alternately for each period, and
for each period, one of the first photodiode and the second photodiode is driven in a reverse-biased manner and to become active.

5. The detection device according to claim 2, wherein
in a first period, the first photodiode is driven in a reverse-biased manner, the first light source is controlled to be on, and the second light source is controlled to be off,
in a second period, the second photodiode is driven in a reverse-biased manner, the first light source is controlled to be on, and the second light source is controlled to be off,
in a third period, the second photodiode is driven in a reverse-biased manner, the second light source is controlled to be on, and the first light source is controlled to be off, and
in a fourth period, the first photodiode is driven in a reverse-biased manner, the second light source is controlled to be on, and the first light source is controlled to be off.

6. The detection device according to claim 2, wherein
in a first period, the first photodiode is driven in a reverse-biased manner, the first light source is controlled to be on, and the second light source is controlled to be off,
in a second period, the first photodiode is driven in a reverse-biased manner, the second light source is controlled to be on, and the first light source is controlled to be off,
in a third period, the second photodiode is driven in a reverse-biased manner, the first light source is controlled to be on, and the second light source is controlled to be off, and
in a fourth period, the second photodiode is driven in a reverse-biased manner, the second light source is controlled to be on, and the first light source is controlled to be off.

7. The detection device according to claim 2, comprising a sensor provided with a plurality of the first photodiodes and a plurality of the second photodiodes, wherein
the first light source comprises a plurality of first light-emitting elements configured to emit light in the first wavelength range and a plurality of second light-emitting elements configured to emit light in the second wavelength range,
the first light-emitting elements and the second light-emitting elements are provided outside one side of the sensor and alternately arranged along the one side,
the second light source comprises a plurality of third light-emitting elements configured to emit light in the third wavelength range and a plurality of fourth light-emitting elements configured to emit light in the fourth wavelength range, and
the third light-emitting elements and the fourth light-emitting elements are provided outside another side of the sensor and alternately arranged along the other side.

8. The detection device according to claim 1, wherein
the first wavelength range is a wavelength range of red light,
the second wavelength range is a wavelength range of green light, and
the third wavelength range is a wavelength range of blue light.

9. The detection device according to claim 2, wherein
the first wavelength range is a wavelength range of red light,
the second wavelength range is a wavelength range of green light,
the third wavelength range is a wavelength range of blue light, and
the fourth wavelength range is a wavelength range of near-infrared light.

10. The detection device according to claim 1, wherein
in each of the first photodiode and the second photodiode, a lower electrode, a lower buffer layer, a first active layer, an upper buffer layer, a second active layer, and an upper electrode are stacked in the order as listed,
the first active layer is sensitive to the first wavelength range, and
the second active layer is sensitive to the second wavelength range and the third wavelength range.

11. The detection device according to claim 2, wherein
in each of the first photodiode and the second photodiode, a lower electrode, a lower buffer layer, a first active layer, an upper buffer layer, a second active layer, and an upper electrode are stacked in the order as listed,
the first active layer is sensitive to the first wavelength range and the fourth wavelength range, and
the second active layer is sensitive to the second wavelength range and the third wavelength range.

12. The detection device according to claim 10, wherein
the first active layer is formed of PCDTBT:PC70BM, and
the second active layer is formed of 1a:fullerene (C₆₀).

13. The detection device according to claim 11, wherein
the first active layer is formed of a mixture of PCDTBT:C70BM and DPP-DTT:PC70BM, and
the second active layer is formed of 1a:fullerene (C₆₀).
